(19) United States
(12) Patent Application Publication
(10) Pub. No.: US 2025/0220323 A1
(43) Pub. Date: Jul. 3, 2025

(54) SOLID-STATE IMAGING DEVICE

(71) Applicant: Panasonic Intellectual Property Management Co., Ltd., Osaka (JP)

(72) Inventors: Motonori ISHII, OSAKA FU (JP); Yuki SUGIURA, OSAKA FU (JP); Yusuke SAKATA, OSAKA FU (JP)

(21) Appl. No.: 18/851,181

(22) PCT Filed: Mar. 20, 2023
(86) PCT No.: PCT/JP2023/011001

§ 371 Date: Sep. 26, 2024

(30) Foreign Application Priority Data
Mar. 29, 2022 (JP) 2022-054417

(51) Int. Cl. H04N 25/77; H10F 30/225

(52) U.S. Cl. CPC H04N 25/77; H10F 30/225

(57) ABSTRACT

A solid-state imaging device of this embodiment includes a plurality of pixels. Each pixel includes an APD and a first element that is a variable resistor or a switch, one end of which is connected to one end of the APD. Other ends of the plurality of first elements are connected in parallel. Other ends of the plurality of APDs are connected in parallel and connected to a variable resistor. A resistance value of the variable resistor is controlled by a control device.

### TECHNICAL FIELD

The present disclosure relates to a solid-state imaging device.

### BACKGROUND ART

In recent years, high-sensitivity photodetectors have been used in various fields such as medical care, communications, biology, chemistry, monitoring, in-vehicle use, and radiation detection. An avalanche photodiode (hereinafter also referred to as an “APD”) is used as one of the means for increasing the sensitivity. The APD is a photodiode that improves the photo detection sensitivity by multiplying signal charges generated by photoelectric conversion using avalanche breakdown.

An optical sensor and a sensing device, each including an APD, are disclosed in Patent Documents 1 and 2, respectively.

In Patent Document 1, a single photon avalanche diode (SPAD) is connected with a transistor (resistance component) via a switch. After avalanche multiplication occurs in the SPAD, the switch is turned on. Accordingly, a current flows through the transistor and the potential of the SPAD decreases. Thus, the avalanche multiplication of the SPAD can be converged.

In Patent Document 2, one photodiode is connected in parallel with a plurality of quenching resistors. A switch is provided between the photodiode and each of the quenching resistors. In Patent Document 2, the output voltage of the photodiode can be controlled by controlling each switch.

### CITATION LIST

### Patent Documents

Patent Document 1: Japanese Unexamined Patent Publication No. 2020-61558
Patent Document 2: Japanese Unexamined Patent Publication No. 2016-225453

### SUMMARY OF THE INVENTION

### Technical Problem

In some cases, a reset transistor is connected between an APD and a power supply that supplies a voltage for resetting the APD, and a quenching resistor is provided between the other power supply and the APD. In this configuration, a period (reset period) for resetting the APD by turning on the reset transistor is provided. If the number of photons entering the APD is large in the reset period of the APD, a larger current occurs in the APD. At this time, due to an IR drop at the quenching resistors, a voltage is not sufficiently applied to the APD, and the APD is not sufficiently reset. Thus, the Geiger multiplication cannot be generated in the exposure time.

It is an object to the present disclosure to provide a solid-state imaging device where even if the number of photons entering the APDs is large, the APDs can be reset.

### Solution to the Problem

In order to achieve the objective, a solid-state imaging device of an embodiment of the present disclosure includes: a plurality of pixels, wherein each of the pixels includes an APD, and a first element that is a variable resistor or a switch, one end of which is connected to one end of the APD, other ends of the plurality of first elements are connected in parallel, other ends of the plurality of APDs are connected in parallel and connected to a first resistor, and a resistance value of the first resistor is controlled by a control device.

### Advantages of the Invention

According to the present disclosure, even if the number of photons entering the APDs is large, the APDs can be reset.

### BRIEF DESCRIPTION OF THE DRAWINGS

FIG. 1 is a block diagram of an exemplary configuration of a solid-state imaging device of a first embodiment.

FIG. 2 is a block diagram of another exemplary configuration of the solid-state imaging device of the first embodiment.

FIG. 3 is a block diagram of another exemplary configuration of the solid-state imaging device of the first embodiment.

FIG. 4 is a block diagram of another exemplary configuration of the solid-state imaging device of the first embodiment.

FIG. 5 is a block diagram of another exemplary configuration of the solid-state imaging device of the first embodiment.

FIG. 6 is a block diagram of another exemplary configuration of the solid-state imaging device of the first embodiment.

FIG. 7 is a timing diagram of a pixel circuit of the first embodiment.

FIG. 8 is a block diagram of an exemplary configuration of a solid-state imaging device of a second embodiment.

FIG. 9 is a block diagram of a distance measuring system of a third embodiment.

### DESCRIPTION OF EMBODIMENTS

Embodiments of the present invention will be described in detail with reference to the drawings. The following description of advantageous embodiments is only an example in nature, and is not intended to limit the scope, applications, or use of the present disclosure.

In the following description, “one end” of a transistor refers to either one of a source and a drain of the transistor, and “the other end” of the transistor refers to the other one of the source and the drain of the transistor.

### First Embodiment

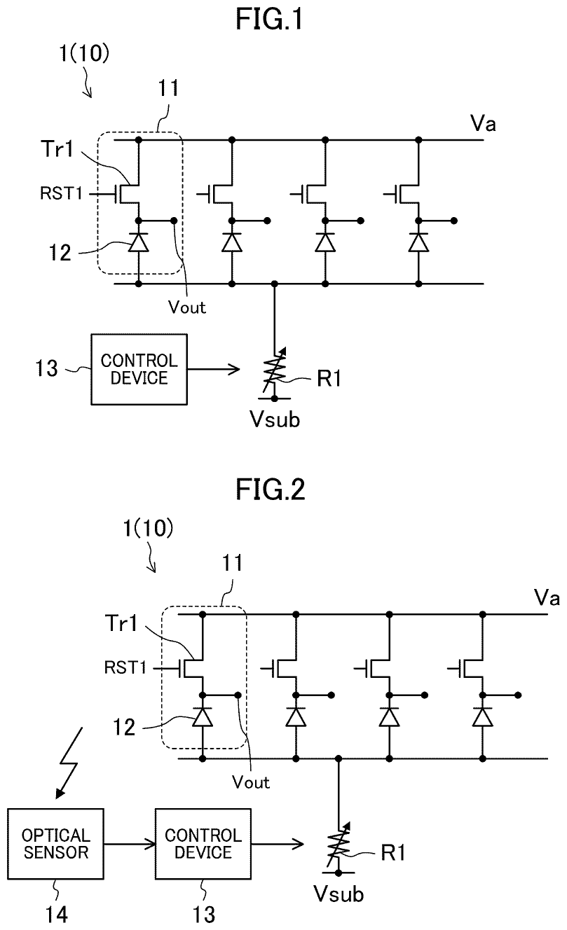

FIG. 1 is a block diagram of an exemplary configuration of a solid-state imaging device of the first embodiment. A solid-state imaging device 1 of this embodiment includes a pixel array circuit 10.

The pixel array circuit 10 includes a plurality of pixel circuits 11 (pixels) and a variable resistor R1. One end of the variable resistor R1 is connected to a voltage Vsub.

A control device 13 is, e.g., an electric circuit and controls a resistance value of the variable resistor R1.

Each pixel circuit 11 includes an APD 12 and a transistor Tr1 (first element).

Specifically, a cathode (one end) of the APD 12 is connected to one end of the transistor Tr1. In each pixel circuit 11, a node is provided between the cathode of the APD 12 and the one end of the transistor Tr1, and outputs an output signal Vout of the pixel circuit 11.

An anode (the other end) of the APD 12 is connected with the other APDs 12 and the variable resistor R1 (first resistor). The other end of the transistor Tr1 is connected in parallel to the other ends of the transistors Tr1 of the other pixel circuits 11, and a power of a first power supply Va is supplied to the other end of the transistor Tr1. The transistor Tr1 has a gate for receiving a reset signal RST1.

In FIG. 1, the transistor Tr1 is an N-type transistor, but may be a P-type transistor, or may be a variable resistor, a switch, or the like.

In the solid-state imaging device 1, the voltage of the APD 12 is reset in a reset period, the APD 12 is exposed in an exposure period after the reset period, and a signal (output signal Vout) indicating a result of exposure is output (read out) from the pixel circuit 11 in a readout period after the exposure period. The transistor Tr1 of each pixel circuit 11 receives the reset signal RST1 at a high level and is turned on (becomes conductive) in the reset period, and receives the reset signal RST1 at a low level and is turned off (becomes non-conductive) in the exposure period. If the transistor Tr1 is a variable resistor, the resistance value of the transistor Tr1 decreases in the reset period and increases in the exposure period.

Here, the resistance value R of the variable resistor R1 is set to a value satisfying the following Expression (1) by the control device 13.

$$\begin{matrix}[ Math 1 ] & \\ R > \frac{2}{kC} \frac{{E}_{BD}^{2} W ln ( \frac{{CV}_{ex}^{2} W ( a α ( {E}_{BD} ) + b β ( {E}_{BD} ) )}{q} )}{( a α ( {E}_{BD} ) + b β ( {E}_{BD} ) ) {V}_{ex} {v}_{s , e} ln ( 2 )} & Expression ( 1 )\end{matrix}$$

$$where$$

$$\begin{matrix}[ Math 2 ] & \\ α ( E ) = {α}_{0} ( - \frac{a}{E} ) β ( E ) = {β}_{0} ( - \frac{b}{E} ) & \end{matrix}$$

α is an impact ionization rate of electrons of the APD, β is an impact ionization rate of holes of the APD, α₀ and a are impact ionization coefficients of electrons of the APD, β₀ and b are impact ionization coefficients of electrons of the APD, vₑₓ is a reverse bias further applied to the APD against a breakdown voltage, v₀ is a reverse bias applied to the APD in an initial state (t=0), W is a width of a depletion layer in the APD, E is a field intensity, q is an elementary charge, C is a cathode capacitance of the APD, v_{s, e} is a saturation rate of electrons, v_{s, h} is a saturation rate of holes, N_{C} is the number of electrons accumulated at a capacitor of a cathode of the APD, E_{BD} is an internal field intensity at the time of application of a breakdown voltage to the APD, k is expressed by nE₁MT, n is the number of photons incident on a pixel per unit time, E₁ is a photon detection efficiency, M is the number of pixels of a sensor that detects photons, and T is a time from the occurrence to the end of avalanche multiplication in the APD. Typically, K is equal to 600, where n=4×108 (number/s), E=0.015, M=106 (number), and T=100 (ps).

For example, as the number of photons entering the APD 12 increases, the number of charges (holes) output from the anode of the APD 12 increases. In particular, in this embodiment, the anodes of the plurality of APDs 12 are connected to each other, and thus if the number of APDs 12 having received photons is large, a large number of charges are generated by the plurality of APDs 12, and the voltage of the anode increases.

To address the problem, in this embodiment, the variable resistor R1 is connected in parallel to the anodes of the plurality of APDs 12. The resistance value of the variable resistor R1 is set to satisfy Expression (1). As shown in Expression (1), the resistance value of the variable resistor R1 is set in accordance with the number of APDs 12 having received photons (this is because k=nE₁MT), and thus if avalanche multiplication occurs in the plurality of APDs 12, an IR drop by the variable resistor R1 is adjusted to an optimum value, and an excessive IR drop can be prevented. Accordingly, the APDs 12 can be reset. That is, even if the number of photons entering the APDs is large, the APDs can be reset.

### (First Variation)

FIG. 2 is a block diagram of another exemplary configuration of the solid-state imaging device of the first embodiment. In comparison with FIG. 1, FIG. 2 shows that the solid-state imaging device 1 includes an optical sensor 14.

The optical sensor 14 detects the amount of light from a subject. The optical sensor 14 outputs data indicating the detected amount of light to the control device 13. Based on the data input from the optical sensor 14, the control device 13 sets the resistance value R of the variable resistor R1 so that the resistance value R satisfies Expression (1). Accordingly, the APDs 12 can be more reliably reset.

### (Second Variation)

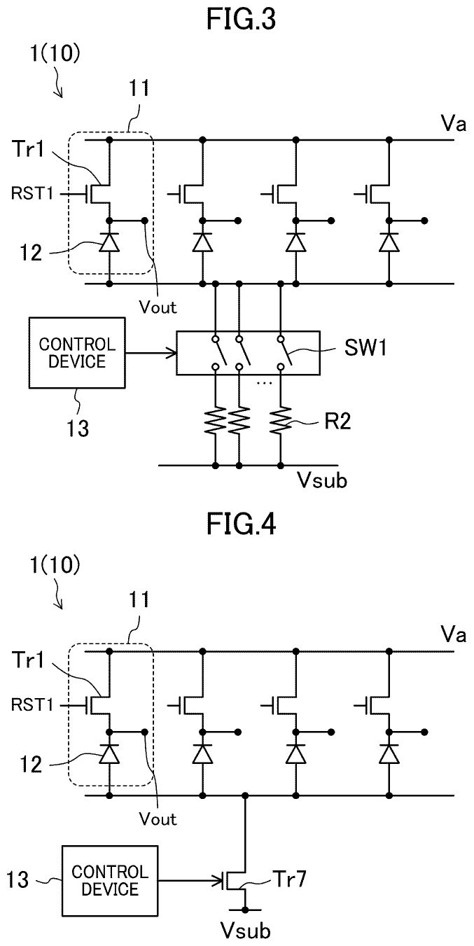

FIG. 3 is a block diagram of another exemplary configuration of the solid-state imaging device of the first embodiment. In comparison with FIG. 1, FIG. 3 shows that the pixel array circuit 10 is connected in parallel with to a plurality of resistors R2 (second resistors) instead of the variable resistor R1.

Specifically, the cathodes of the APDs 12 of the pixel circuit 11 are connected in parallel with the plurality of resistors R2. Each resistor is connected with the cathodes of the APDs 12 via a switch SW1 (first switch).

The control device 13 controls on/off of each switch SW1, thereby changing the number of resistors R2 connected to the anodes of the APDs 12 of the pixel circuit 11. Accordingly, the resistance value of the resistor connected to the anodes of the APDs 12 of the pixel circuit 11 can be set to satisfy Expression (1).

### (Third Variation)

FIG. 4 is a block diagram of another exemplary configuration of the solid-state imaging device of the first embodiment. In comparison with FIG. 1, FIG. 4 shows that the pixel array circuit 10 is connected with a transistor Tr7 (first transistor) instead of the variable resistor R1.

The control device 13 inputs a signal (voltage) to the gate of the transistor Tr7, thereby operating the transistor Tr7 in a saturated region. For example, the time of operating the transistor Tr7 in the saturated region is controlled, so that the transistor Tr7 can be operated similarly to the variable resistor R1. Accordingly, the same advantages as those of FIG. 1 can be achieved.

### (Fourth Variation)

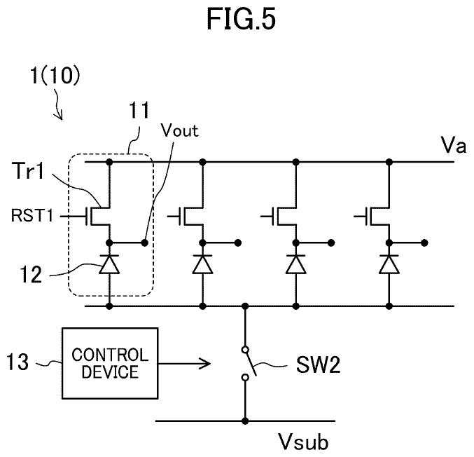

FIG. 5 is a block diagram of another exemplary configuration of the solid-state imaging device of the first embodiment. In comparison with FIG. 1, FIG. 5 shows that the pixel array circuit 10 is connected with a switch SW2 (second switch) instead of the variable resistor R1.

The control device 13 controls on/off of the switch SW2. At this time, the control device 13 controls a switching frequency of the switch SW2, thereby operating the switch SW2 similarly to the variable resistor R1. Accordingly, the same advantages as those of FIG. 1 can be achieved.

### (Fifth Variation)

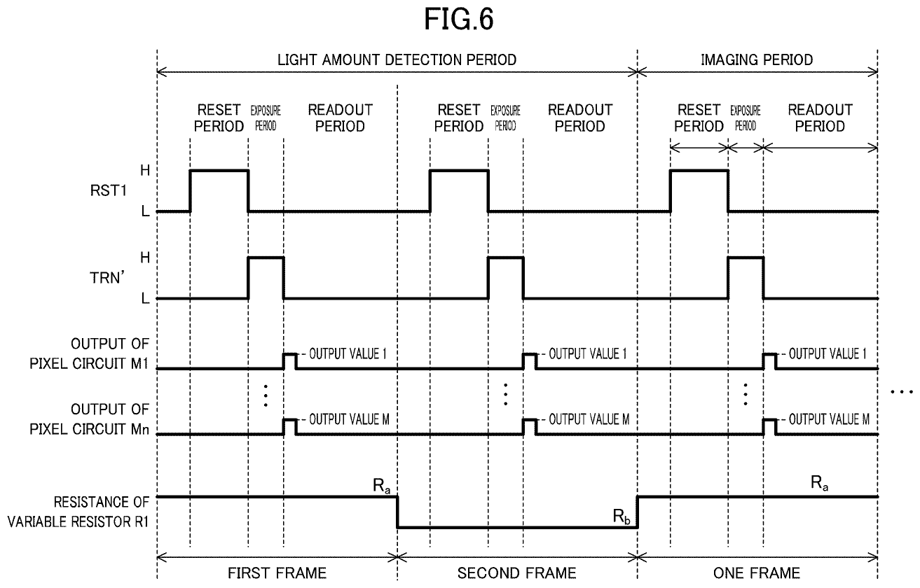

FIG. 6 is an exemplary timing diagram of the pixel circuit of the first embodiment. FIG. 6 shows a reset signal RST1, an exposure gate signal TRN′, outputs of the pixel circuits M1 to Mn (output signals Vout), and a resistance value of the variable resistor R1. In the following description, “H” indicates that a signal is at a high level, and “L” indicates that a signal is at a low level. Each exposure gate signal TRN′ is a signal indicating whether the APD 12 is exposed. The outputs of the pixel circuits M1 to Mn indicate output values of the signals output from the first to N-th pixel circuits 11.

In FIG. 6, a light amount detection period is set before an imaging period. The light amount detection period includes a first and second frames, each including a reset period, an exposure period, and a readout period. As shown in FIG. 6, the first frame and the second frame have different resistance values of the variable resistor R1. Accordingly, the first frame and the second frame have different output values of the signals output from the pixel circuits M1 to Mn. In this variation, the resistance value R of the variable resistor R1 is set to a resistance value of a frame where the mean value of outputs of the pixel circuits M1 to Mn is highest. Specifically, in FIG. 6, the resistance value R of the variable resistor R1 is set to Ra (the resistance value of the first frame). Accordingly, the resistance value of the variable resistor R1 can be set so that the output of the pixel circuit 11 increases.

### Second Embodiment

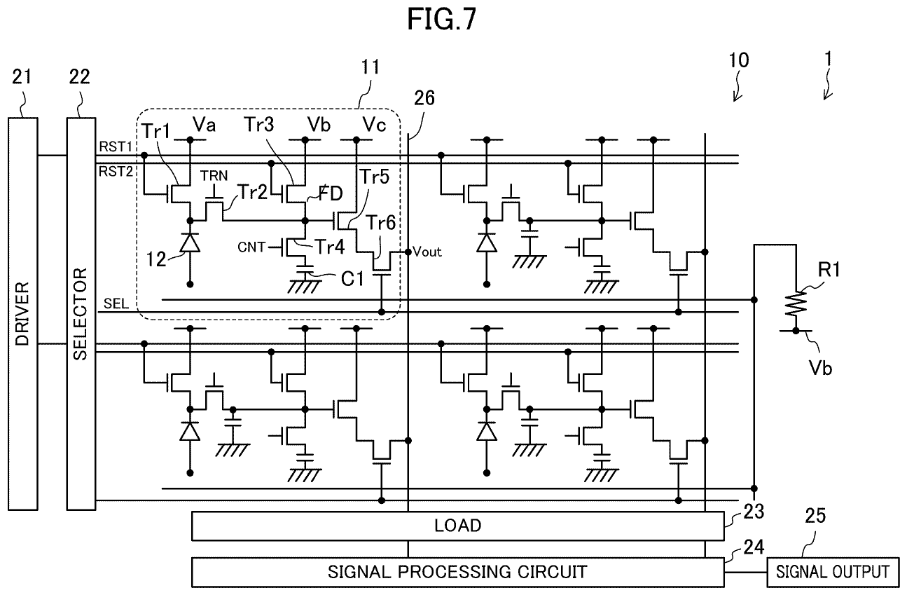

FIG. 7 is a block diagram of an exemplary solid-state imaging device of a second embodiment. FIG. 7 shows that, in addition to the configuration of FIG. 1, the solid-state imaging device 1 includes a driver 21, a selector 22, a load 23, a signal processing circuit 24, and a signal output section 25.

A pixel array circuit 10 includes a plurality of pixel circuits 11. FIG. 7 shows that, in addition to the configuration of FIG. 1, each pixel circuit 11 further includes a transistor Tr2 (transfer transistor), a transistor Tr3 (reset transistor), a transistor Tr4 (storage transistor), a transistor Tr5 (source follower transistor), a transistor Tr6 (selection transistor), and a capacitor C1.

One end of the transistor Tr2 is connected to one end of the transistor Tr1 and a cathode of the transistor APD 12, the other end of the transistor Tr2 is connected to a floating diffusion FD (hereinafter simply referred to as “FD” in some cases), and a gate of the transistor Tr2 receives a transfer signal TRN. One end of the transistor Tr3 is connected to a second power supply Vb, the other end of the transistor Tr3 is connected to the FD, and a gate of the transistor Tr3 receives a reset signal RST2. One end of the transistor Tr4 is connected to the FD, the other end of the transistor Tr4 is connected to one end of the capacitor C1, and a gate of the transistor Tr4 receives a count signal CNT. One end of the transistor Tr5 is connected to a third power supply Vc, the other end of the transistor Tr5 is connected to one end of the transistor Tr6, and a gate of the transistor Tr5 is connected to the FD. A gate of the transistor Tr6 receives a selection signal SEL and the other end (an output signal Vout) of the transistor Tr6 is connected to a signal output line 26.

The driver 21 outputs the reset signal RST1 to the gate of the transistor Tr1 of each pixel circuit 11 in order to drive the transistor Tr1. The driver 21 outputs the reset signal RST2 to the gate of the transistor Tr3 of each pixel circuit 11 in order to drive the transistor Tr2. The selector 22 outputs the selection signal SEL to the gate of the transistor Tr6 in order to drive the transistor Tr6. The signal processing circuit 24 is connected with the signal output line 26 via the load 23 and receives the output signal Vout output from each pixel circuit 11. The signal processing circuit 24 performs predetermined processing on the received output signal Vout and outputs a signal to the signal output section 25. The signal output section 25 is, e.g., a PC or a display, and generates a result as numerical data, image data, or the like of detection by the solid-state imaging device 1 based on the signal input from the signal processing circuit 24.

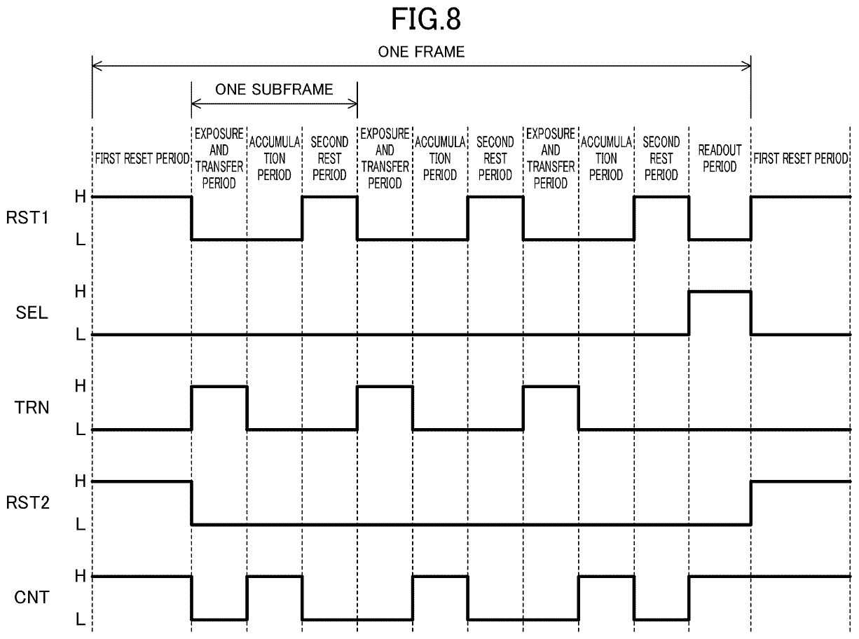

FIG. 8 is a timing diagram of each pixel circuit of the second embodiment. In FIG. 8, one frame includes a first reset period, a plurality of subframes (three subframes in FIG. 8), and a readout period. The subframes include an exposure and transfer period, an accumulation period, and a second reset period. The pixel circuit 11 repeatedly executes the operation defined in one frame. Note that one frame may include two or more subframes.

In the first reset period, the reset signal RST1 is at a high level, the transfer signal TRN is at a low level, the reset signal RST2 is at a low level, the count signal CNT is at a high level, and the selection signal SEL is at a low level. Thus, the transistor Tr1 is turned on, the transistor Tr2 is turned off, the transistor Tr4 is turned on, the transistor Tr5 is turned on, and the transistor Tr6 is turned off. Accordingly, in the reset period, the APD 12 is reset to the voltage value of the first power supply Va, and the voltage value of the FD is reset to the voltage value of the second power supply Vb. The APD 12 and the FD are reset at the same time in the reset period, but individual periods for resetting the APD 12 and the FD may be provided in the reset period.

In the exposure and transfer period, the reset signal RST1 is at a low level, the transfer signal TRN is at a high level, the reset signal RST2 is at a low level, the count signal CNT is at a low level, and the selection signal SEL is at a low level. Thus, the transistor Tr1 is turned off, the transistor Tr2 is turned on, the transistor Tr3 is turned off, the transistor Tr4 is turned off, and the transistor Tr6 is turned off. Accordingly, in the exposure and transfer period, if receiving incident light, the APD 12 generates (exposes) a signal charge through avalanche multiplication, and thus the cathode voltage of the APD 12 changes. In addition, the signal charge generated by the APD 12 is accumulated in the FD via the transistor Tr2. In the exposure and transfer period, the exposure of the APD 12 and the transfer of the signal charges to the FD are performed at the same time. Alternatively, in the exposure and transfer period, the exposure period of the APD 12 and the transfer period of the signal charges may be provided individually.

In the accumulation period, the reset signal RST1 is at a low level, the transfer signal TRN is at a low level, the reset signal RST2 is at a low level, the count signal CNT is at a high level, and the selection signal SEL is at a low level. Thus, the transistor Tr1 is turned off, the transistor Tr2 is turned off, the transistor Tr3 is turned off, the transistor Tr4 is turned on, and the transistor Tr6 is turned off. Accordingly, in the accumulation period, the signal charges accumulated in the FD are transferred to the capacitor C1 and accumulated in the capacitor C1.

In the second reset period, the reset signal RST1 is at a high level, the transfer signal TRN is at a low level, the reset signal RST2 is at a low level, the count signal CNT is at a low level, and the selection signal SEL is at a low level. Thus, the transistor Tr1 is turned on, the transistor Tr2 is turned off, the transistor Tr3 is turned off, the transistor Tr4 is turned off, and the transistor Tr6 is turned off. Accordingly, in the second reset period, the voltage of the APD 12 is reset to the voltage value of the first power supply Va, and thus the APD 12 can be exposed to light in the subsequent light exposure period. In the second reset period, the count signal CNT may be at a low level and the transistor Tr4 may be turned on.

In the readout period, the reset signal RST1 is at a low level, the transfer signal TRN is at a low level, the reset signal RST2 is at a low level, the count signal CNT is at a high level, and the selection signal SEL is at a high level. Thus, the transistor Tr1 is turned off, the transistor Tr2 is turned off, the transistor Tr3 is turned off, the transistor Tr4 is turned on, and the transistor Tr6 is turned on. Accordingly, in the readout period, the signal charges accumulated in the capacitor C1 are output (read out) to the signal processing circuit 24 via the signal output line 26 and the load 23.

### (Distance Measuring System)

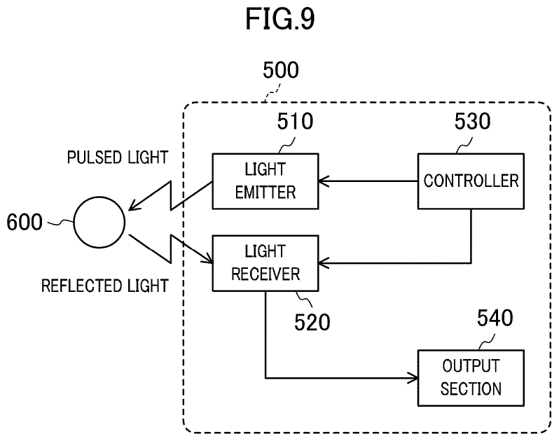

FIG. 9 is a block diagram of a distance measuring system of a third embodiment. A distance measuring system 500 includes a light receiver 520 including the solid-state imaging device 1, a light emitter 510 that emits light toward a measurement target 600, a controller 530 that controls the light receiver 520 and the light emitter 510, and an output section 540 that receives a signal corresponding to the light reflected by the measurement target 600 from the light receiver 520 and calculates a distance to the measurement target 600.

The distance measuring system 500 including the solid-state imaging device 1 with a higher sensitivity can reduce erroneous distance detection and can obtain a distance to the measurement target 600 with high accuracy.

In the foregoing, the embodiments as exemplary techniques disclosed in the present application have been described. However, the technique in the present disclosure is not limited to the embodiments, and is also applicable to embodiments where modifications, substitutions, additions, or omissions are made appropriately.

### DESCRIPTION OF REFERENCE CHARACTERS

1 Solid-State Imaging Device
11 Pixel Circuit (Pixel)
12 APD
13 Control Device
14 Optical Sensor
R1 Variable Resistor (First Resistor)
R2 Resistor (Second Resistor)
SW1 Switch (First Switch)
SW2 Switch (Second Switch)
Tr1 Transistor (First Element)
Tr7 Transistor (First Transistor)

1. A solid-state imaging device comprising:
a plurality of pixels,
wherein
each of the pixels includes
an APD, and
a first element that is a variable resistor or a switch, one end of which is connected to one end of the APD,
other ends of the plurality of first elements are connected in parallel,
other ends of the plurality of APDs are connected in parallel and connected to a first resistor, and
a resistance value of the first resistor is controlled by a control device.

2. The solid-state imaging device of claim 1, wherein
the control device sets the resistance value R of the first resistor to satisfy the following Expression (1):
$$\begin{matrix}[ Math 1 ] & \\ R > \frac{2}{kC} \frac{{E}_{BD}^{2} W ln ( \frac{{CV}_{ex}^{2} W ( a α ( {E}_{BD} ) + b β ( {E}_{BD} ) )}{q} )}{( a α ( {E}_{BD} ) + b β ( {E}_{BD} ) ) {V}_{ex} {v}_{s , e} ln ( 2 )} & Expression ( 1 )\end{matrix}$$
$$where$$
$$\begin{matrix}[ Math 2 ] & \\ α ( E ) = {α}_{0} ( - \frac{a}{E} ) β ( E ) = {β}_{0} ( - \frac{b}{E} ) & \end{matrix}$$
and α is an impact ionization rate of electrons of the APD, β is an impact ionization rate of holes of the APD, α₀ and a are impact ionization coefficients of electrons of the APD, β₀ and b are impact ionization coefficients of electrons of the APD, vₑₓ is a reverse bias further applied to the APD against a breakdown voltage, V is a reverse bias applied to the APD, v₀ is a reverse bias applied to the APD in an initial state (t=0), W is a width of a depletion layer in the APD, E is a field intensity, q is an elementary charge, C is a cathode capacitance of the APD, v_{s, e} is a saturation rate of electrons, v_{s, h} is a saturation rate of holes, N_{C} is the number of electrons accumulated at a capacitor of a cathode of the APD, E_{BD} is an internal field intensity at the time of application of a breakdown voltage to the APD, k is expressed by nE₁MT, n is the number of photons incident on a pixel per unit time, E₁ is a photon detection efficiency, M is the number of pixels of a sensor that detects photons, and T is a time from the occurrence to the end of avalanche multiplication in the APD.

3. The solid-state imaging device of claim 2, wherein
the control device sets the resistance value of the first resistor based on an output from an optical sensor that detects an amount of light from a subject.

4. The solid-state imaging device of claim 1, wherein
the first resistor includes a plurality of second resistors connected in parallel, and
each of the second resistors is connected to the other end of the APD via a first switch.

5. The solid-state imaging device of claim 1, wherein
the first resistor consists of a first transistor that is a transistor, and
the control device controls a voltage that is to be input to a gate of the first transistor.

6. The solid-state imaging device of claim 1, wherein
the solid-state imaging device uses the control device to perform a plurality of times of exposure so that the resistance value of the first resistor varies, and
the control device sets the resistance value of the first resistor to a resistance value that maximizes outputs of the plurality of pixels.

7. The solid-state imaging device of claim 1, wherein
the solid-state imaging device reduces the resistance value of the first element or turns on the first element, thereby resetting the APD,
after the APD is reset, the solid-state imaging device reduces the resistance value of the first element or turns on the first element, thereby exposing the APD, and
after the APD is exposed, a signal is read out from the pixel.

8. A solid-state imaging device comprising:
a plurality of pixels,
wherein
each of the pixels includes
an APD, and
a first element that is a variable resistor or a switch, one end of which is connected to one end of the APD,
other ends of the plurality of first elements are connected in parallel,
other ends of the plurality of APDs are connected in parallel and connected to a second switch, and
a switching frequency of the second switch is controlled by a control device.
